(19) United States
(12) Patent Application Publication
(10) Pub. No.: US 2002/0152442 A1
(43) Pub. Date: Oct. 17, 2002

(54) Error correction code circuits

(76) Inventor: Jeng-Jye Shau, Palo Alto, CA (US)

Correspondence Address: Bo-In Lin, 13445 Mandoli Drive, Los Altos Hills, CA, 94022, US

(21) Appl. No.: 10/038,268

(22) Filed: Oct. 22, 2001

Related U.S. Application Data
(63) Continuation-in-part of application No. 08/989,841, filed on Dec. 12, 1997, now Pat. No. 6,216,246.
(63) Continuation-in-part of application No. 08/653,620, filed on May 24, 1996, now Pat. No. 5,748,547.
(60) Provisional application No. 60/317,873, filed on Sep. 7, 2001.

(51) Int. Cl. H03M 13/00

(52) U.S. Cl. 714/779

(57) ABSTRACT

This invention discloses a method for changing a configuring ot an error correction code (ECC) logic circuit for performing an error-check of a changed data-width. The method includes the steps of: A) sequentially interconnecting a set of N1 identical error-check blocks where N1 is a first positive integer. And, the method further includes a step B) of reconfiguring the ECC logic circuit by changing the ECC logic circuit to a set of N2 sequentially interconnected circuits comprising N2 of the identical error-check blocks where N2 is a second positive number. In a preferred embodiment, the step of sequentially interconnecting a set of N1 identical error-check blocks is a step of interconnecting the N1 error-check blocks only between sequentially neighboring blocks for transmitting signals only between the neighboring error-check blocks. And, the step of reconfiguring the ECC logic circuit by changing the ECC logic circuit to a set of N2 sequentially interconnected circuits is a step of interconnecting the N2 error-check blocks only between sequentially neighboring blocks for transmitting signals only between the neighboring error-check blocks.

This is a Continuous-In-Part (CIP) Application of a previously filed co-pending application with Ser. No. 08/989,841 filed on Dec. 12, 1997 and 08/989,841 is a Continuation-in-Part of another Application 08/653,620 filed on Mar. 24, 1996 by identical sole inventor as for this Continuation-in-Part (CIP) Application.

### BACKGROUND OF THE INVENTION

1. Field of the Invention

The present invention relates to error correction code (ECC). More particularly, this invention is related to device and applications of the ECC circuits for error corrections of data with variable data width.

2. Description of the Related Art

Data correction by applying the error correction circuit (ECC) is one of many very effective methods to improve data integrity. It is widely used for application s in communication systems or data storage devices. The ECC operation principles can be illustrated by the system block diagram for one example of ECC calculator in FIG. 1. This ECC calculator operates on a predefined data package with a fixed number of bits (64 bits in this example). Selected bits from the raw data package are sent to a plurality of parity trees (8 trees in this example) to calculate the parities of different data sub-sets. Each data sub-set comprises roughly half of the data bits of the data package, while the data in each sub-set partially overlap with the data in other sub-sets. The resulting parity bits (called ECC bits) are combined with the raw data to be transferred or stored. These data sub-sets are chosen in such configurations so that if there are errors introduced into the raw data during data transfer, the error bit is identified by comparing parity bits calculated by the same parity calculations with the original ECC bits.

Prior art ECC mechanism provides excellent protections for data integrity, but it also introduces many technical difficulties. The ECC calculator takes a large number of data into large parity trees while each parity tree executes different parity calculations for different data subsets. The complex wiring needed for such parity calculations make the ECC circuits slow and complex. Performance degradation caused by ECC calculation often limited its applications. Each prior art ECC mechanism is defined for a particular data size. In order to change the size of the data package, it is required to re-design the ECC mechanism. Testing is another issue. The speed of a prior art ECC calculator is strongly dependent on the input data pattern; they always slow down significantly when the size of the data package is increased. If there is a manufacture defect in one of the complex wiring used by a prior art ECC circuit, it is very difficult to detect the problem because of the large number (2⁷²×2⁷² for the example in FIG. 1) of test vectors required to have full fault coverage.

It is therefore highly desirable to develop a high performance ECC mechanism that is simple in structure while it has the flexibility to support different data width.

### SUMMARY OF THE PRESENT INVENTION

The primary objective of this invention is to provide an ECC calculator with simplified structure. This simplified ECC calculator can support data packages of nearly any size using the same circuit at the same speed. Another objective is to improve the speed of ECC circuits. Another primary objective of the present invention is to provide novel applications for practical products using the novel ECC circuits of the present invention.

These and other objectives of the present invention are achieved by providing rotational relationships in the ECC calculation formula. The resulting ECC circuits are built by repeating circuit blocks, while data width can be extended freely. Superior performance is achieved by the simplified circuit structure.

While the novel features of the invention are set forth with particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIG. 1 is a block diagram for prior art ECC circuits;

FIG. 2(a) is a schematic diagram showing the rotational relationship between ECC blocks of the present invention;

FIG. 2(b) is the schematic diagram for the ECC block in FIG. 2(a);

FIG. 2(c) shows the structure of an ECC decoder of the present invention;

FIG. 2(d) is the schematic diagram for the ECC decoder block in FIG. 2(c);

FIG. 3(a) shows a variable width ECC calculator of the present invention;

FIG. 3(b) shows a variable width ECC calculator that allows process of continuous incoming data streams of different data-widths;

FIG. 4 shows the structure of a prior art floating gate device;

FIG. 5 is a float chart for the ECC self repair procedures of the present invention;

FIGS. 6(a-d) illustrates different methods to represent multiple bit digital data with one analog signal;

FIG. 6(e) is the block diagram for a circuit to implement the analog-to-digital data translation according to the table in FIG. 6(b);

FIGS. 7(a-c) show the structures for prior art content addressable memory and its associated memory cells; and

FIGS. 8(a-d) show examples for ECC protection on CAM devices.

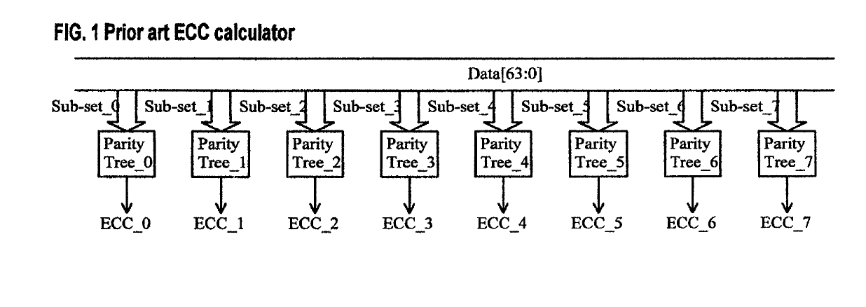

### DETAILED DESCRIPTION OF THE PREFERRED EMBODIMENT

Due to the complexity of the error correction mechanism, the descriptions of this invention will apply the array symbol used for C programming language in the following discussions to describe the mechanism. For example, D[3:2][4:1] means a set of 8 symbols D34, D33, D32, D31, D24, D23, D22, and D21. The symbol “mod” represents the modulation operation with remaining part from a divide operation. For example, [(k+3) mod 8] equals 2 when k=7, and [(k−3) mod 8] equals 6 when k=1. The “mod” function is implemented by a rotational relationship in the input connections of actual circuits.

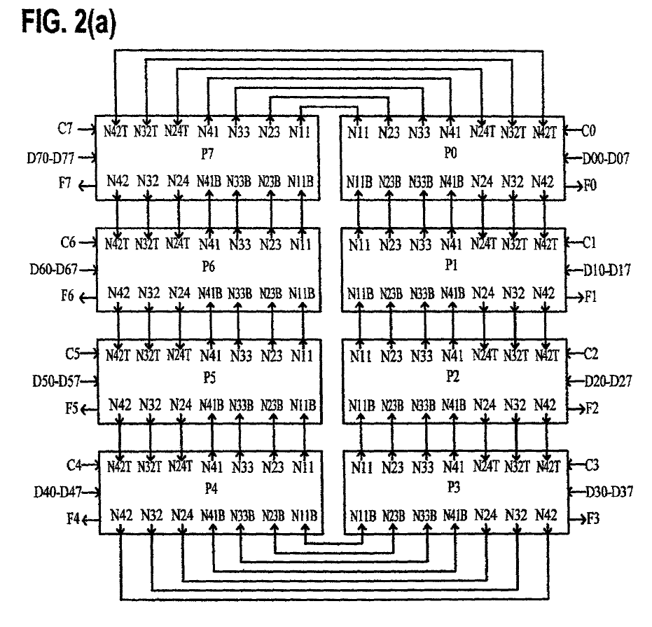

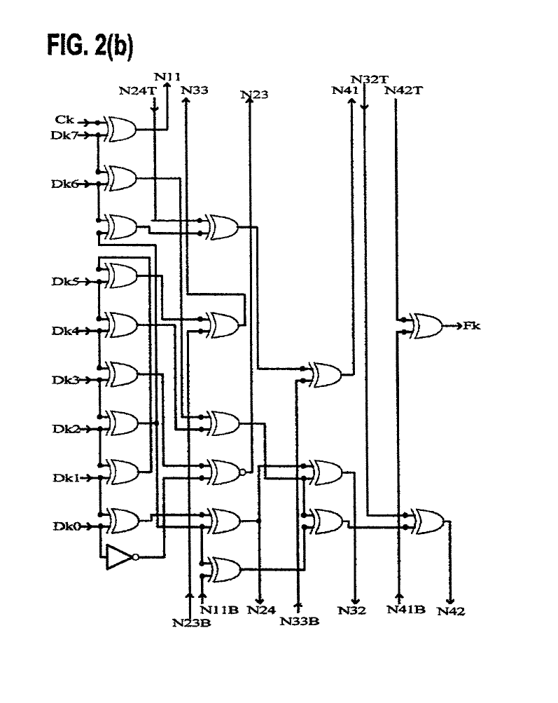

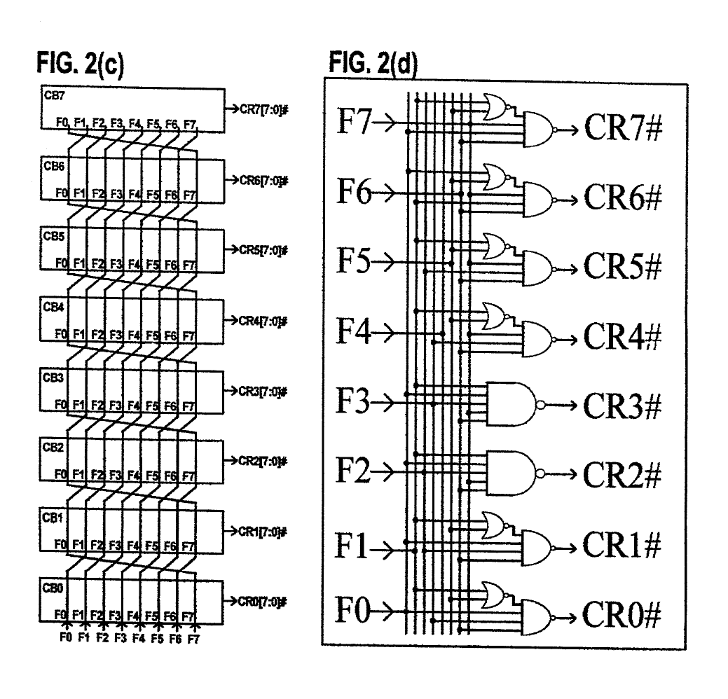

In U.S. Pat. No. 6,216,246, the present inventor disclosed an ECC calculator shown in FIG. 2(a). The ECC calculator in this example takes 64 input data (D[7:0][7:0]). It comprises 8 identical parity circuit blocks (P7-P0). Schematic diagram for the parity circuit block is shown in FIG. 2(b). Each parity circuit block (P7-P0) comprises 19 exclusive-or gates, one exclusive-nor, and one inverter. The parity circuit block P[k] takes data D[k][7:0] and stored ECC bit Ck as inputs, where k is an integer between 0 to 7. It sends four outputs (N11, N22, N33, N41) to the parity circuit on top of it, and receives corresponding outputs (N11B, N22B, N33B, N41B) from the parity circuit below it. It also sends three outputs, i.e., N24, N32, and N42, to the parity circuit below it, and receives the corresponding outputs, i.e., N24T, N32T, and N42T, from the parity circuit below it. It also outputs a correction factor Fk. The logic function of the outputs of the k'th parity circuit (P[k]) can be written as

| | |
|---|---|
| N11 = Parity{Ck, Dk0} | (1a), |
| N23 = Parity{Dk3, Dk4, Dk7} | (1b), |
| N33 = Parity{N23B, Dk2, Dk5, Dk6} | (1c), |
| N41 = Parity{N33B, N24T, Dk1, Dk4, Dk5} | (1d), |
| N24 = Parity{Dk4, Dk5, Dk6, Dk7} | (1e), |
| N32 = Parity{Dk0, Dk1, Dk2, Dk3, Dk4, Dk5, Dk6, Dk7} | (1f), |
| N42 = Parity{N32T, N11B, Dk0, Dk1, Dk2, Dk3, Dk4, Dk5} | (1g), |
| and | |
| Fk = Parity{N42T, N41B} | (1h), |

where “Parity{ }” means the parity value of all the inputs included in “{ }” signs. The inputs (N11B, N22B, N33B, N41B, N24T, N32T, N42T) provided by nearby parity circuits can be determined by the fact that all of those parity circuits are identical. For example, from Eq. (1a) a functional relationship can be established that:

N11B=Parity{C[(k+1)mod 8], D[(k+1)mod 8]0} (2)

where C[(k+1) mod 8] is the stored ECC bit, and D[(k+1) mod 8]0 is the first data connected to the parity circuit below it. All other inputs (N22B, N33B, N41B,N24T, N32T, N42T) can be determined in similar ways. Based on the connections in FIG. 2(b) and Equations. (1a-1h), it can be concluded that

Fk=Parity{Ck, D[(k−2)mod 8][7:0], D[(k−1)mod 8][5:0],

D[k][7:4,0],D[(k+1)mod 8][5,4,1],

D[(k+2)mod 8][6,5,2], D[(k+3)mod 8][7,4,3]} (3)

where k=(0,1,2,3,4,5,6,7).

If there is no error in the input data, the signals (Fk) would be all zeros. If there is one error in the input data D[7:0][7:0], the error bit is identified by checking the correction factors (F0-Fk) using the ECC decoder shown in FIG. 2(c). This ECC decoder comprises 8 ECC decoding blocks (CB0-CB7). Those 8 ECC decoding blocks have identical logic functions, as shown in the schematic diagram in FIG. 2(d). The only difference is in the connection to the Fk signals. There is, again, an rotational relationship in the Fk connections. For example, the F1 of CB1 is equal to F0 of CB0, while the F2 of CB2 is also F0, . . . . etc. The outputs (CR[7:0][7:0]#) of those ECC decoding blocks (CB0-CB7) indicates the location of the error bit. If CRij# is low, that means the value of Dkj should be flipped, where k=(0,1,2,3,4,5,6,7) and j=(0,1,2,3,4,5,6,7).

The same circuit in FIG. 2(a) can be used to calculate the ECC bits for a set of raw data; all the Ck inputs is assigned a value of zero, and the resulting Fk would be the ECC bits as

ECC(k)=Parity{D[(k−2)mod 8][7:0], D[(k−1)mod 8][5:0],

D[k][7:4,0],D[(k+1)mod 8][5,4,1],

D[(k+2)mod 8][6,5,2], D[(k+3)mod 8][7,4,3]} (4)

where ECC(k) is the value of ECC bit, and k=(0,1,2,3,4,5,6,7).

The ECC mechanism shown in FIGS. 2(a-d) is novel by the rotation relationship in the parity calculation; parity calculation of C[k+1] is the result of simple rotation of C[k]. This rotation relationship is also applied to the ECC correction circuits. Such ECC circuits are called “rotational ECC calculator (REC)” in the present invention. The REC circuits are different from other prior art ECC circuits by the following features:

(1)The prior art ECC circuits use different ECC trees to calculate different ECC bits resulting in complex circuits connected by complex wiring. The rotational relationship allows REC to support all the logic calculations using identical building blocks. The design complexity is simplified dramatically.

(2)Each input data in the prior art ECC circuits need to travel long distance to multiple parity trees. For REC, each input data only need to go to one parity circuit block. This simplification dramatically reduces the wiring complexity for the input signals, resulting in significant speed improvements.

(3)The intermediate logic signals (N11, N22, N33, N41,N24, N32, N42) only need to travel to nearby parity circuit block. There is no long signal lines or complex wiring in any part of the whole REC circuits. That is the major reason why REC is always by far faster than other prior art ECC calculators.

(4)Due to the rotational symmetry, the speed of REC circuits is nearly independent of the input data pattern, providing significant improvements in testing, debugging, and optimization procedures.

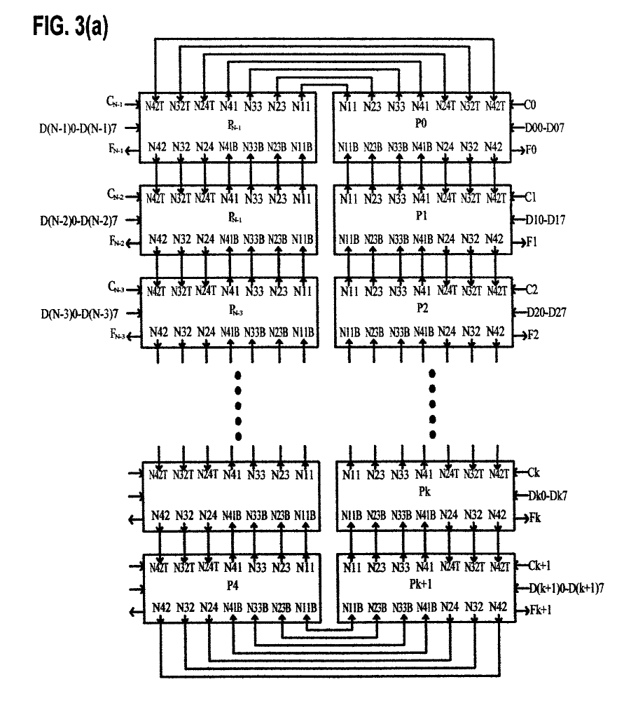

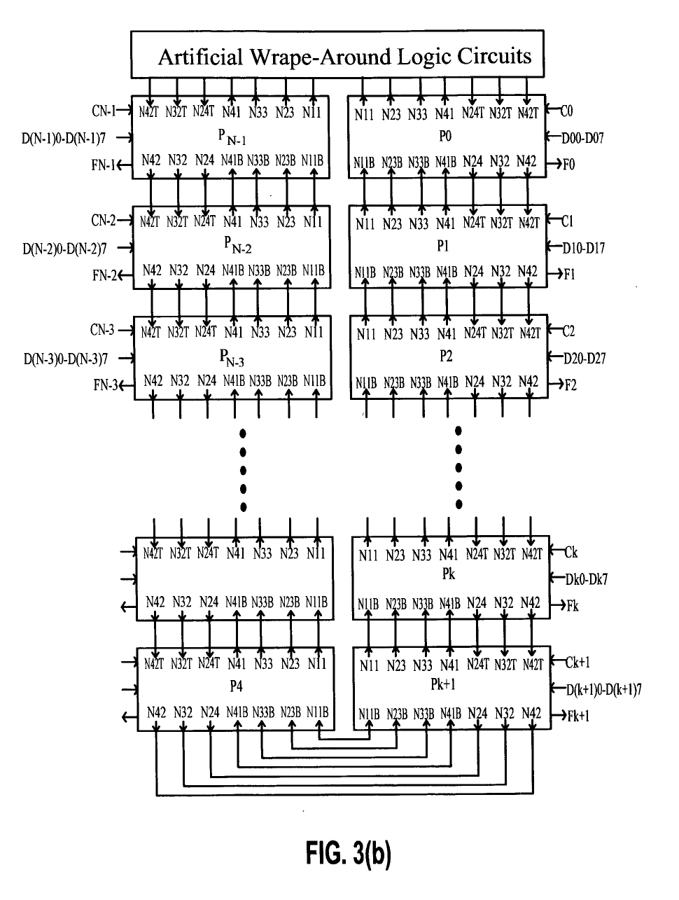

One important feature for REC is that it can support input data of different size with the same repeating circuits. FIG. 3 shows an REC circuit that uses identical circuit blocks as those in FIG. 2(a) to support input data of variable length. The ECC calculator in this example takes N bytes of input data (D[(N−1):0][7:0]), where N is an arbitrary integer. It comprises N identical parity circuit blocks (P_{N-1}−P0) connected in rotation relationship as shown in FIG. 3(a). The logic functions of these parity circuit blocks (P_{N-1}−P0) are identical to that in FIG. 2(b). Equations (1a-h) are still true except that k can be any number between 0 to N−1. Equations (2-4) need to be re-written as

N11B=Parity{C[(k+1)mod N], D[(k+1)mod N]0} (5)

Fk=Parity{Ck, D[(k−2)mod N][7:0], D[(k−1)mod N][5:0],

D[k][7:4,0],D[(k+1)mod N][5,4,1],

D[(k+2)mod N][6,5,2],D[(k+3)mod N][7,4,3]} (6)

ECC(k)=Parity{D[(k−2)mod N][7:0],D[(k−1)mod N][5:0],

D[k][7:4,0],D[(k+1)mod N][5,4,1],

D[(k+2)mod N][6,5,2],D[(k+3)mod N][7,4,3]} (7)

where FCC(k) is the value of ECC bit, and k=(0,1, . . . N−1).

More specifically, the REC circuits in FIGS. 2(a-d) are just a special case when (N=8). A REC can be expanded to support input data set of any number by implementing the same repeating REC building blocks as that shown in FIG. 3(a). The resulting circuits will have identical speed and identical circuit connections, no matter what is the width of the input data set. There is no need to re-design ECC calculator to support different data width. For different types of application, it is also possible to broaden the application of this invention by breaking the closed-loop configuration as that shown in FIG. 3(b). Referring to FIG. 3(b) that shows an alternate preferred embodiment for application to situations often encountered in data communication systems where a long stream of incoming data that starts and ends with pre-defined data, e.g., header records, are received continuously. As that shown in FIG. 3(b), instead of a closed loop REC circuits as that shown above, a series rotational error correction circuits is implemented to continuously receive and process the data stream to assure correction of data transmission. An artificial wrap around logic circuit (AWALC) is implemented wherein the error code calculations are performed by feeding simplified bit patterns such as all ones or all zeros to the beginning and the ending REC calculator blocks. The error code calculations can be carried out similar to the closed loop REC with the fixed bit-pattern input to those blocks. The open loop wrap-around ECC calculator can be conveniently controlled or reconfigure to process data streams of variable lengths by first sending the length of a data record then applying a corresponding number of ECC blocks to carry out the error code calculations.

While specific embodiments of the invention have been illustrated and described herein, it is realized that other modifications and changes will occur to those skilled in the art. For example, Eq. (1-7) can be modified to different forms while keeping the rotation relationship. The parity block can access different numbers of inputs other than 8, and output different number of ECC bits and intermediate signals. The novel element for the correction mechanism of the present invention is to enforce a rotational relationship in parity calculation of ECC mechanism. Based on the rotational relationship, repeating circuit design can be used to simplify design effort. Higher performance is also achieved by minimizing wiring complexity.

According to above descriptions, this invention discloses a method for changing a configuring of an error correction code (ECC) logic circuit for performing an error-check of a changed data-width. The method includes the steps of: A) sequentially interconnecting a set of N1 identical error-check blocks where N1 is a first positive integer. And, the method further includes a step B) of reconfiguring the ECC logic circuit by changing the ECC logic circuit to a set of N2 sequentially interconnected circuits comprising N2 of the identical error-check blocks where N2 is a second positive number. In a preferred embodiment, the step of sequentially interconnecting a set of N1 identical error-check blocks is a step of interconnecting the N1 error-check blocks only between sequentially neighboring blocks for transmitting signals only between the neighboring error-check blocks. And, the step of reconfiguring the ECC logic circuit by changing the ECC logic circuit to a set of N2 sequentially interconnected circuits is a step of interconnecting the N2 error-check blocks only between sequentially neighboring blocks for transmitting signals only between the neighboring error-check blocks.

A system equipped with the above ECC protection mechanism will need additional logic circuits and more data storage resources. These additional resource requirements may appear to increase the cost of the system. In reality, the ECC protection mechanism often helps to reduce the overall cost of practical products. Two practical examples are described in the following discussions to illustrate these points.

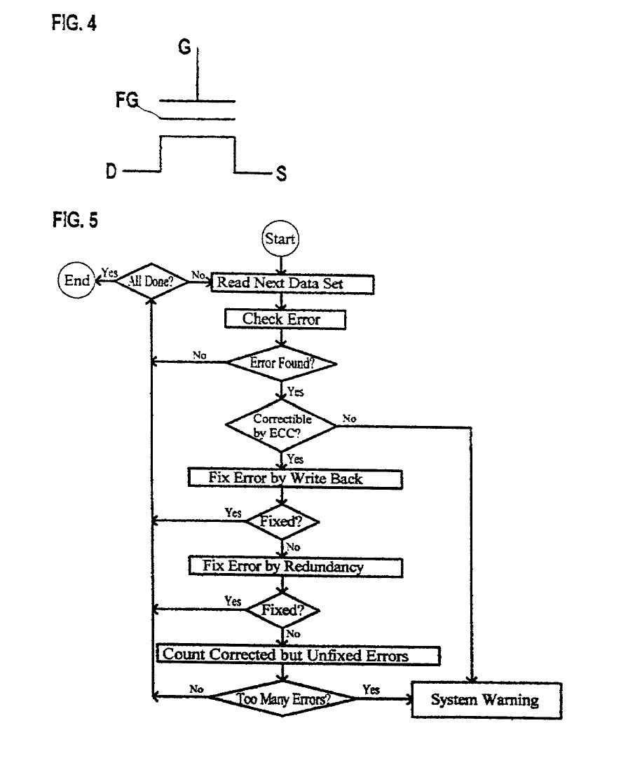

The first example is an application on floating gate devices. FIG. 4 shows the symbolic structure of a floating gate transistor. This transistor comprises source (S), drain (D), and gate (G), just like common transistors. The difference is that it has a floating gate (FG) between gate and channel region. The floating gate is isolated under most operation conditions, while charges can be injected into or removed from it by hot carrier mechanism or tunneling mechanism during a program or an erase operation. The conductivity of the floating gate device is a function of the amount of charge trapped in the floating gate (FG). It is therefore possible to store data into the floating gate device by changing the amount of trapped charges in the floating gate. Many commercial products, such as EPROM, EEPROM, and FLASH, have been built on the floating gate devices. The most difficult reliability problems for floating gate devices are the charge loss (QL) problem and program-erase (PE) cycling induced failures. The QL problem is often caused by manufacture defects on the surrounding insulators around the floating gate. A manufacture defect can cause small leakage on the floating gate so that the device is not able to maintain its data due to loss in trapped charges. The QL problem usually does not cause permanent damages to the floating gate device; if the data is re-written into the failed device, it will maintain functional for a period of time until its trapped charges gradually leak out. The PE cycle induced failures are often permanent. When a user executes a program to erase a floating gate device many times, the high energy charges going through the floating gate causes damages to its surrounding materials, so that the device may fail after certain PE cycles. Normal floating gate devices always has excellent tolerance to QL and PE cycle requirements; the failures are usually causes by manufacture defects. Current art floating gate products comprises millions of memory cells, while its QL and PE cycle tolerance is determined by the worst bit out of those millions of cells. It is therefore possible to introduce significant reliability improvements using ECC to protect a floating gate product. The reliability properties of a device protected by ECC are no longer determined by the worst bits in the device. Instead, it is determined by the intrinsic properties of the device; the resulting products usually are by far more reliable. The ECC circuits are also capable of knowing the correct data while part of the stored data are faulty. It is therefore possible to correct the source of the problem, instead of correcting the outputs only. FIG. 5 shows the float chart for an ECC self-repair procedure. This self-repair procedure can be started by an external system such as a computer software. It also can be started internally while external users do not know it happened. For example, execution of the procedure can be invoked during a power up initialization cycle, or a timer signal is used to trigger the procedure. Assume that the ECC bits have been written into the memory device together with the raw data. After the self-repair procedure is started, a data set is read from the memory device with associated ECC bits. ECC circuits are used to check if there is any error in the raw data. If there is no error, the error-check operation progress to next data set until the procedures are completed. If an error is found, and ECC can not correct it, the device will send out a warning signal to the system. If ECC is able to correct the problem, a corrected data bit is written back into the storage device. If the problem is caused by a soft error such as charge loss problem in floating gate device, or a problem caused by alpha particles, the problem may be resolved by writing the correct data back into the memory device. The faulty data should be read and checked again. If the problem has been fixed, the error code checking operation can now move to operate on the next data set. If the problem can't be fixed by write back, a programmable redundancy circuit maybe implemented to resolve the problems caused by the faulty memory cells. If the redundancy circuit is able to fix the problem, the error-check operation progresses to next data set. If not, the product is still functional because a user will obtain the correct data after ECC corrections. However, if there are too many failures corrected by ECC, the device maybe getting close to fatal failures. A counter may be implemented to count the number of corrected failures. If the number is larger than a pre-defined value, warning signals are generated to notify the user of the system. The above self-repair procedures are not restricted to the use of the REC circuits of the present invention. However, even that prior art ECC circuit may be able to carry out similar functions, the REC of this invention provides the advantages to significantly reduce the areas required for adding the ECC circuits while increasing the speed of error code-check operation.

According to above descriptions, this invention further discloses a method for operating a memory device comprising a plurality of memory cells. The method includes a step A) of performing an error-check on said memory cells. And, B) repairing a faulty memory cell storing an error data bit. In a preferred embodiment, the step of repairing a faulty memory cell further includes a step of performing the step of repairing the faulty memory cell automatically by writing a correct bit into the faulty memory cell.

While specific embodiments of the invention have been illustrated and described herein, it is realized that other modifications and changes will occur to those skilled in the art. Details in the self-repair procedures can be changed for different applications. For example, one may not want to use write back fix mechanism, another may not have redundancy fix. It is also possible to introduce other types of fixes such as timing adjustment. Another possibility is to do the self-repair procedures under a stress condition so that potential failures can be detected and fixed before they can cause problems at normal working conditions. For example, the self-repair procedures may be executed at lower voltage or higher temperatures. The above method can be implemented to any storage device or systems. Its applications are not limited to floating gate devices.

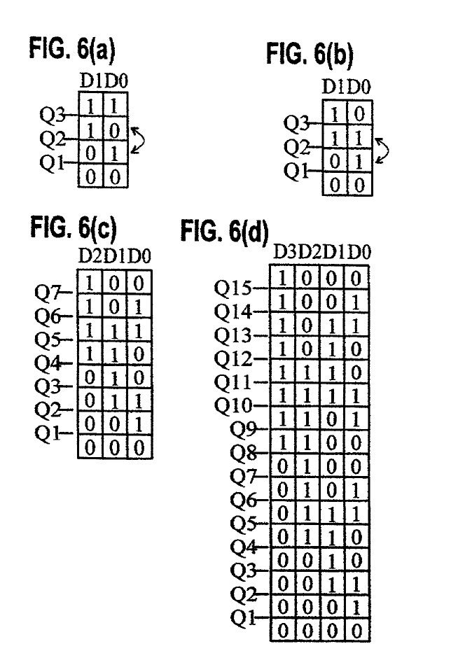

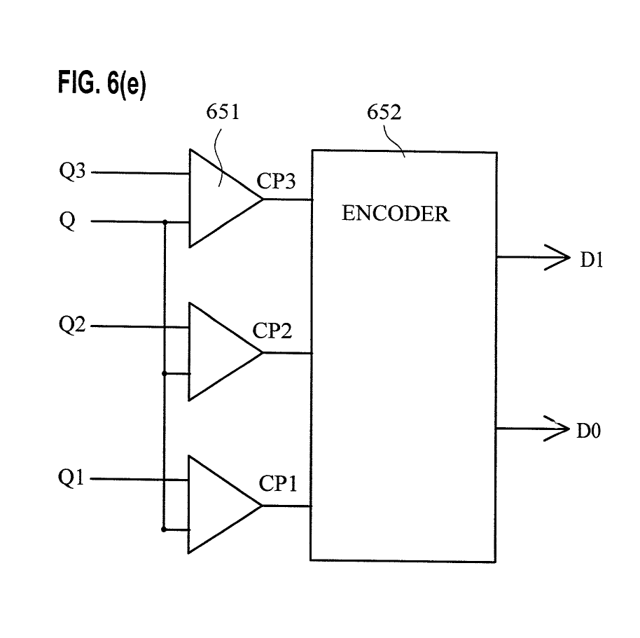

Implementing ECC protections or the self-repair mechanism will require additional resources, but the resulting product maybe more cost efficient due to better yield and or better reliability. It is also possible to use the improvement in reliability to carry more data in the same device. For example, four analog levels are defined for representing the amount of floating gate trapped charge, so that one memory cell now may be used to store two bits of binary data, instead of one bit. FIG. 2(a) shows one example of this multiple level digital data (MLDD) representation. The two bit binary data (1,1) is stored when the trapped charges (Q) in a floating gate device is more than a pre-defined value (Q3) as Q>Q3; binary data (1,0) is stored when Q3>Q>Q2; binary data (0,1) is stored when Q2>Q>Q1; and binary data (0,0) is stored when Q<Q1; where Q3, Q2, and Q1 are a pre-defined values related to the trigger level of sensing circuits and Q3>Q2>Q1. Using this method, double amount of data are stored when compared to conventional memory cells, while in the meantime, the margin for error is increased by four times. ECC protection will make such method practical by correcting failures. The self-repair mechanism of the present invention will make it more reliable by fixing failures. The MLDD representation in FIG. 2(a) has one problem. If the original storage data is (1,0) while Q3>Q>Q2, and the device lose some charges so that Q2>Q>Q1, the data become (0,1). There can be two binary bits changed due to a small amount of charge loss. The ECC protection needs to be able to correct two bits, otherwise, two separated ECC circuits are required to protect those two bits separately. Both methods require more resources. This resource requirement can be reduced if the two bit MLDD representation is redefined as that shown in FIG. 2(b). For each higher step of Q, the binary data never changes more than one bit. Therefore, the resource requirements will be simplified to fix small charge loss. Similar methods can be applied to the 8-level-3-bit example in FIG. 6(c), and the 16-level-4-bit example in FIG. 6(d).

FIG. 6(e) is the block diagram for a circuit to implement the analog-to-digital data translation according to the table in FIG. 6(b). An analog signal (Q) is compared with three pre-defined values (Q3, Q2, Q1) by comparators (651). For example, the output of the first comparator (CP1) is 1 when Q>Q1 while it is 0 when Q<Q1; the output of the second comparator (CP2) is 1 when Q>Q2 while it is 0 when Q<Q2; and the output of the third comparator (CP3) is 1 when Q>Q3 while it is 0 when Q<Q3. These outputs (CP3, CP2, CP1) of comparators are sent to an encoder (652) circuit. This encoder (652) provides two digital output bits (D1, D0). The values of (D1, D0) are (1,0) when CP3 CP2=CP1=1; the values of (D1, D0) are (1,1) when CP3=0, while CP2=CP1=1; The values of (D1, D0) are (0,1) when CP3=CP2=0, while CP1=1; and the values of (D1, D0) are (0,0) when CP3=CP2=CP1=0. The tables in FIGS. 6(c,d) can be implemented in similar circuits.

According to above descriptions, this invention further discloses a memory device that includes a plurality of memory cells each having a floating gate for storing a plurality of electric charges therein. The memory device further includes an error-check logic circuit that includes a set of identical error-check blocks sequentially interconnected for checking errors of data storage in the memory cells. In a preferred embodiment, the memory device further includes a multiple-level voltage means for applying at least two electrical charge levels on the floating gates for representing at least two binary bits stored in the memory cells. In a preferred embodiment, the memory device further includes a multiple-level electrical-charge sensing means for sensing at least two electric-charge levels stored in the floating gates for detecting at least two binary bits stored in the memory cells. In another preferred embodiment, the multiple-level electrical-charge sensing means further comprising a bit-pattern means for generating a bit-pattern based on the electric-charge levels sensed by the multiple-level electrical-charge sensing means. In another preferred embodiment, the bit-pattern means is further provided for generating a sequence of bit-patterns based on the electric-charge levels wherein each of the bit patterns based on a first electrical-charge level differing by only a single bit from a second bit-pattern representing a second electrical-charge level sequentially adjacent to the first electrical-charge level.

While specific embodiments of the invention have been illustrated and described herein, it is realized that other modifications and changes will occur to those skilled in the art. The above method can be applied to other types of devices using other types of parameters. For example, Q can be any analog parameter such as voltage or current, it does not need to be the trapped charge. The device also does not need to be a floating gate device.

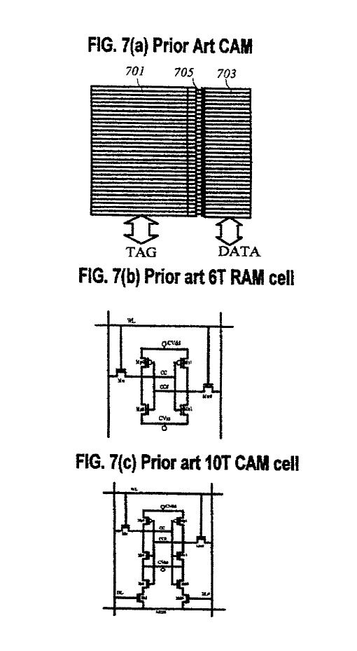

Another example of implementation is the application of ECC protection on content addressable memory (CAM). FIG. 7(a) shows the basic structures of a prior art CAM device. There are two kinds of data stored in a CAM device—common digital data stored in typical random access memory (RAM) array (703), and the addressing data (called “TAG” in IC industry) stored in CAM array (701). FIG. 7(b)is the schematic for a typical memory cell in the RAM array (703). This memory cell use four transistors (Mp0, Mp1, Mn0, Mn1) to form a bi-stable latch to store data, and two transistors (Mw, Mw#) for selecting the memory cell through word line (WL). FIG. 7(c) is the schematic for a typical memory cell in the CAM array (701). This memory cell is similar to the RAM cell except that it has four more transistors (Mc0, Mc1, Mc0#, Mc1#) forming an XOR gate to compare new TAG placed on bit lines (BL, BL#) with the storage data (CC, CC#). If the storage data and the bit line values are different, the miss line (MISS#) will be pulled down. Each row in the CAM array (701) comprises a plurality of CAM cells with their MISS# line connected together. When any one bit in one row of the stored TAG is different from the TAG that is been looked up, the MISS# line will be low. The MISS# line (705) of each TAG row is used to control the word line (WL) of one corresponding RAM row. Only when the row with the same stored TAG as the look up TAG will be selected, so that its stored data can be read from the RAM array. Such CAM device in FIG. 7(a) is a powerful device for simultaneous lookup a large number of stored addresses, while reading out the desired data with the right addresses. Due to this parallel look up operation, prior art CAM does not have ECC protection. In order to assure that the results of a TAG lookup is correct, it is necessary to assure that there is no faulty bit in the whole TAG array during the lookup process. That would require one ECC calculator for every row of the CAM array and that is too expensive and the ECC protection would not be practically useful. Therefore, prior art CAM products often fail due to reliability problems such as alpha particle induced soft error.

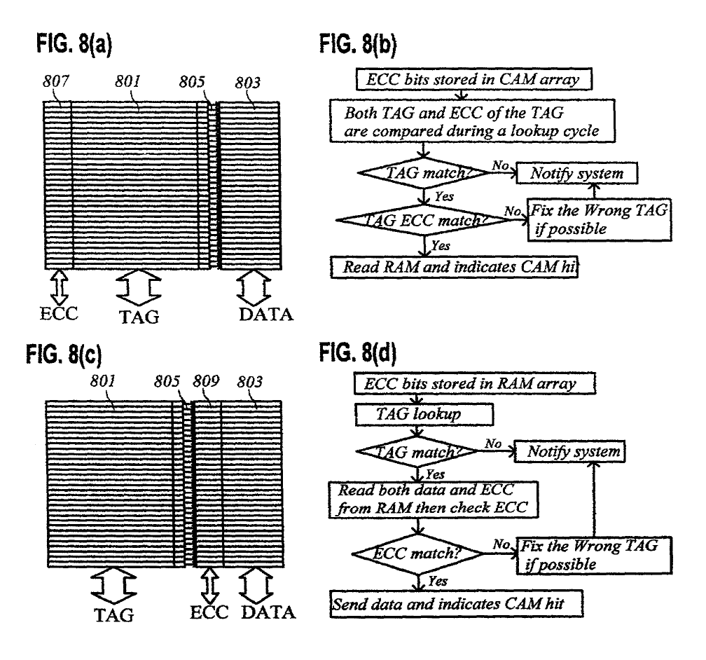

However, for practical purposes of providing ECC protection in a CAM lookup operation, it is realized that simultaneous ECC protection all the rows in the CAM is not necessary. Instead, because only the matched stream of data-bits is used of subsequent operations, it is only required to protect the row that matches during a CAM lookup. FIG. 8(a) is a block diagram for a CAM protected by ECC. This CAM device still have the same CAM array (801) for TAG lookup, and the same RAM array (803) to store data. The structure and memory cells used by the TAG array (801) and the RAM array (803) are identical to those shown in FIGS. 7(a-c). For each set of TAG data, its ECC bits calculated by ECC circuits are also stored into a CAM array (807). This ECC CAM array (807) can be separated from or merged with the TAG CAM array (801). FIG. 8(b)is a flow chart showing the look up procedures for the CAM in FIG. 8(a). During the look up, both TAG and its ECC bits are compared. If there is no match, notification operation is carried out by the system as usual. If there is a TAG match while its ECC bits also match, data transmission of the matched data is carried out as usual. If there is a TAG match while its ECC bits do not match, that means it is a false match. It is required to notify the system about this false match and treat it as a mismatch. An attempt to fix the problem may be carried out by writing the correct value determined by ECC back into the CAM array. If there are more than one TAG match found in the TAG array, the one with ECC match is the real match. Only the correct data bit stream is transmitted, while an operation to fix the wrong TAG is also performed with a notification sent to the system about such an data error and correction events. The RAM array also can have its own ECC bits to protect RAM data. Another example is to save ECC bits in a RAM array instead of the CAM array as shown in FIG. 8(c). The look up procedures are shown in FIG. 8(d). During a TAG look up, only TAG is compared. If there is no match, notification of no-matches found is carried out by the system as usual. If there is a TAG match, both data and ECC bits from the RAM array are read. This ECC bits can be just for the TAG. It is also possible to include both data and TAG into the ECC calculations to protect both. After ECC calculation, if no errors are detected, transmission of the data and claim TAG hit is carried out by the system as usual. If errors are detected by ECC, it is necessary to notify the system about this false match and treat it as a mismatch. An attempt to fix the problem may be carried out by writing the correct value determined by ECC back into the CAM and RAM array. The example in FIG. 8(c) uses less resource than the example in FIG. 8(a). When there are multiple matches found in the TAG array, the structure in FIG. 8(c) can not distinguish which one is the right match.

According to above descriptions, this invention further discloses a content addressable memory (CAM) device. The CAM memory device includes a plurality of memory-cell arrays for storing an array content therein provided for an data-access to an array based on a match with the array content. The CAM device further includes an error-check logic circuit for checking errors of the data access to each of the memory-cell arrays. In a preferred embodiment, the CAM device further includes an error-code storage means for storing an error-code check (ECC) bit for each of the memory-cell array used by the error-check logic circuit for checking errors of the data access to each of the memory-cell arrays. In another preferred embodiment, each of the memory-cell array further storing an error-code check (ECC) bit generated by the error-check logic circuit for checking errors of the data access to each of the memory-cell arrays. In another preferred embodiment, the error-code storage means is a random access memory (RAM) device for storing the error-code check (ECC) bit for each of the memory-cell array used by the error-check logic circuit for checking errors of the data access to each of the memory-cell arrays.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

I claim:

1. A method for changing a configuring of an error correction code (ECC) logic circuit for performing an error-check of a changed data-width comprising:
sequentially interconnecting a set of N1 identical error-check blocks where N1 is a first positive integer; and
reconfiguring said ECC logic circuit by changing said ECC logic circuit to a set of N2 sequentially interconnected circuits comprising N2 of said identical error-check blocks where N2 is a second positive number.

2. The method of claim 1 wherein:
said step of sequentially interconnecting a set of N1 identical error-check blocks is a step of interconnecting said N1 error-check blocks only between sequentially neighboring blocks for transmitting signals only between said neighboring error-check blocks; and
said step of reconfiguring said ECC logic circuit by changing said ECC logic circuit to a set of N2 sequentially interconnected circuits is a step of interconnecting said N2 error-check blocks only between sequentially neighboring blocks for transmitting signals only between said neighboring error-check blocks.

3. A method for operating a memory device comprising a plurality of memory cells, comprising:
performing an error-check on said memory cells; and
repairing a faulty memory cell storing an error data bit.

4. The method of claim 3 wherein:
said step of repairing a faulty memory cell further comprising a step of performing said step of repairing said faulty memory cell automatically by writing a correct bit into said faulty memory cell.

5. A memory device comprising a plurality of memory cells each having a floating gate for storing a plurality of electric charges therein, said memory device further comprising:
an error-check logic circuit includes a set of identical error-check blocks sequentially interconnected for checking errors of data storage in said memory cells.

6. The memory device of claim 5 further comprising:
a multiple-level voltage means for applying at least two electrical charge levels on said floating gates for representing at least two binary bits stored in said memory cells.

7. The memory device of claim 6 further comprising:
a multiple-level electrical-charge sensing means for sensing at least two electric-charge levels stored in said floating gates for detecting at least two binary bits stored in said memory cells.

8. The memory device of claim 7 wherein:
said multiple-level electrical-charge sensing means further comprising a bit-pattern means for generating a bit-pattern based on said electric-charge levels sensed by said multiple-level electrical-charge sensing means.

9. The memory device of claim 7 wherein:
said bit-pattern means is further provided for generating a sequence of bit-patterns based on said electric-charge levels wherein each of said bit patterns based on a first electrical-charge level differing by only a single bit from a second bit-pattern representing a second electrical-charge level sequentially adjacent to said first electrical-charge level.

10. A memory device comprising a plurality of memory cells each having at least two memory-cell characteristic-states each representing a bit-pattern stored therein, said memory device further comprising:
an error-check logic circuit includes a set of identical error-check blocks sequentially interconnected for checking errors of data storage in said memory cells.

11. A content addressable memory (CAM) device comprising a plurality of memory-cell arrays for storing an array content therein provided for an data-access to an array based on a match with said array content, said CAM device further comprising:
an error-check logic circuit for checking errors of said data access to each of said memory-cell arrays.

12. The content addressable memory (CAM) device of claim 11 further comprising:
an error-code storage means for storing an error-code check (ECC) bit for each of said memory-cell array used by said error-check logic circuit for checking errors of said data access to each of said memory-cell arrays.

13. The content addressable memory (CAM) device of claim 11 wherein:
each of said memory-cell array further storing an error-code check (ECC) bit generated by said error-check logic circuit for checking errors of said data access to each of said memory-cell arrays.

14. The content addressable memory (CAM) device of claim 11 wherein:
said error-code storage means is a random access memory (RAM) device for storing said error-code check (ECC) bit for each of said memory-cell array used by said error-check logic circuit for checking errors of said data access to each of said memory-cell arrays.

15. A memory device comprising a plurality of memory cells each having a floating gate for storing a plurality of electric charges therein, said memory device further comprising:
a multiple-level electrical-charge sensing means for sensing at least two electric-charge levels stored in said floating gates as a sequence of charge levels for detecting at least two binary bits for recording a plurality of bit patterns stored in said memory cells;
said multiple-level electrical-charge sensing means further includes a bit-pattern means for generating a sequence of bit-patterns based on said sequence of electric-charge levels wherein each of said bit patterns based on a first electrical-charge level differing by only a single bit from a second bit-pattern represented by a second electrical-charge level sequentially adjacent to said first electrical-charge level.

16. An analog sensing device comprising:
an analog signal sensing means for sensing a sequence of analog signal-levels for generating a sequence of bit patterns corresponding to said analog signal-levels wherein each of said signal levels representing a bit pattern differing by a single bit from another bit pattern representing an adjacent signal level.
